(19) United States
(12) Patent Application Publication
(10) Pub. No.: US 2014/0120299 A1
(43) Pub. Date: May 1, 2014

(54) ANTI-SHRINK PLASTIC SHELL

(71) Applicants: Hong Fu Jin Precision Industry (ShenZhen) Co., Ltd., (US); HON HAI PRECISION INDUSTRY CO., LTD., New Taipei (TW)

(72) Inventor: YA-PING TENG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/873,182

(22) Filed: Apr. 29, 2013

(30) Foreign Application Priority Data
Oct. 30, 2012 (CN) 2012205621673

(51) Int. Cl. H05K 5/02

(52) U.S. Cl. CPC H05K 5/0208
USPC 428/99

(57) ABSTRACT

An anti-shrink plastic shell with lug boss for preventing shrinking is provided. An anti-shrink plastic shell comprises a base; at least one lug boss protruding from an inner surface of the plastic shell; the lug boss includes a pillar and a support portion positioned between the base and the pillar; the support portion comprises a platform which is perpendicular to the pillar and at least one support leg which is perpendicular to the platform, and the at least one support leg is perpendicularly protruding from the inner surface of the base to support the platform.

### BACKGROUND

1. Technical Field

The present disclosure relates to plastic shells, particularly to a plastic shell with an anti-shrink lug boss.

2. Description of Related Art

Electronic devices, such as telephones, e-readers include a plastic shell formed by two sub plastic shells engaging with each other. Usually, one of the sub plastic shells defines a number of lug bosses, which are protruding from the inner surface of the sub plastic shell and resisting on the other sub plastic shell. Namely, the greater depth of the sub plastic shell, the greater height of the lug bosses. The lug bosses are formed integrally with the sub plastic shell by injection molding.

Moreover, it is necessary to take a larger draft angle on the external surface of the lug bosses to easily remove the lug bosses from a mold, namely the diameter of free end of the lug bosses is less than that of the other end of the lug bosses. If the diameter of the free ends of the lug bosses is constant and the draft angle on the external surface of the lug bosses is constant, the height of the lug bosses is higher. Thus, the diameter of the other end of the lug bosses would be much larger than that of the free end of the lug bosses, and the thickness of the whole lug bosses would thus be not even. A plastic shell, which has unevenly thick lug bosses will shrink during injection molding.

Therefore, what is needed is a plastic shell with an anti-shrinkage lug boss to overcome the above mentioned limitations.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of a plastic shell with lug boss in one embodiment.

FIG. 2 is an enlarged view of the circled portion II of the FIG. 1.

FIG. 3 is an isometric view of a plastic shell with lug boss in another embodiment.

FIG. 4 is an enlarged view of the circled portion IV of FIG. 3

### DETAILED DESCRIPTION

The disclosure including the accompanying drawings, is illustrated by way of example and not by way of limitation. It should be noted that references to “an” or “one” embodiment in this disclosure are not necessarily to the same embodiment, and such references mean at least one.

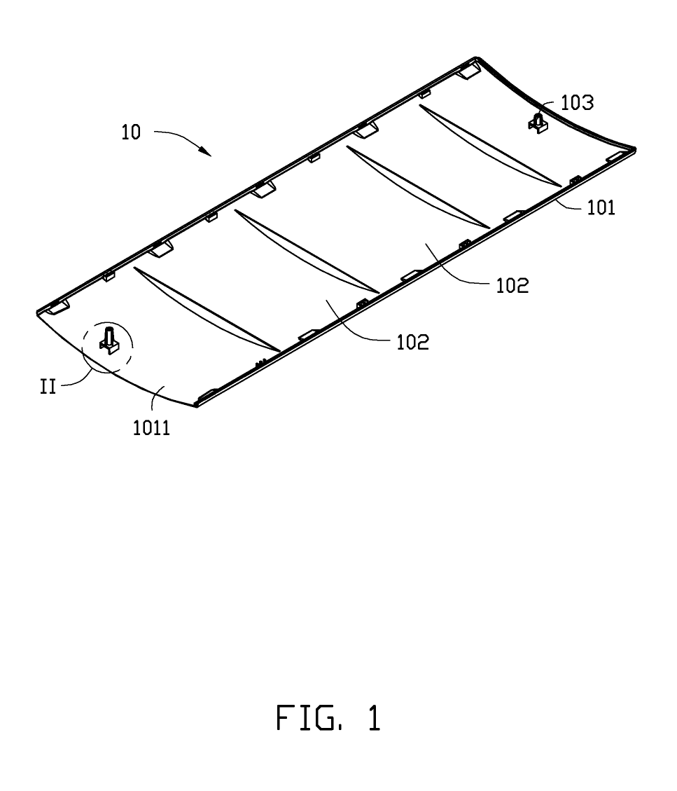

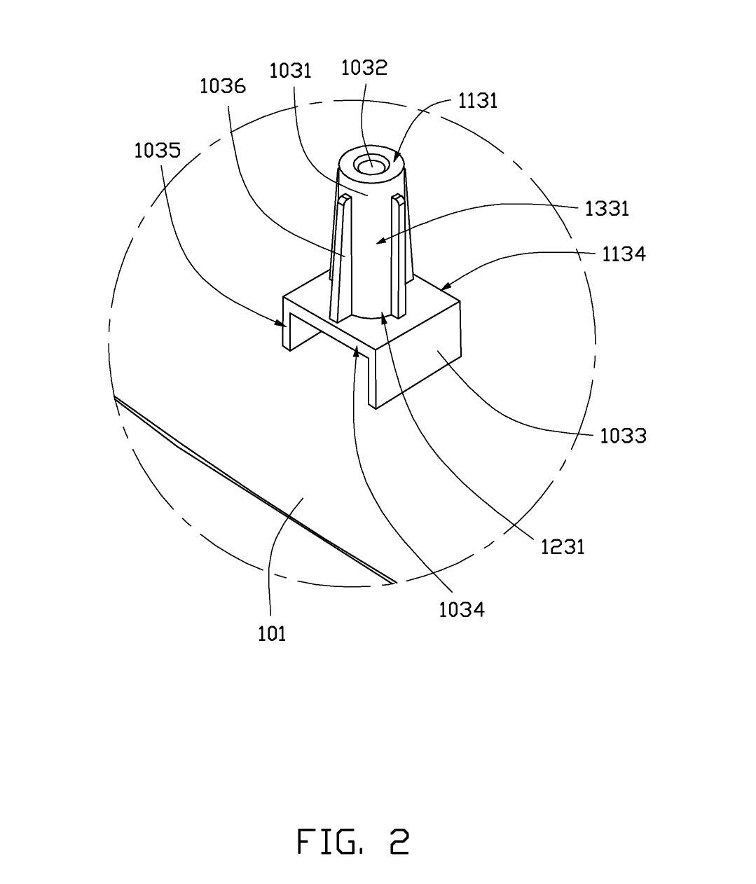

FIGS. 1 and 2 show a plastic shell 10 of the embodiment. The plastic shell 10 includes a base 101 and at least one lug boss 103 protruding from the inner surface 1011 of the plastic shell 10 and resisting on the other plastic shell (not shown). The at least one lug boss 103 is formed together with the base 101 by injection molding. The inner surface 1011 of the base 10 defines at least one cavity 102. The cavities 102 are used for accommodating a variety of electronic components (not shown) and structural elements (not shown). The lug boss 103 includes a pillar 1031 and a support portion 1033. The support portion 1033 is positioned on the base 101 and the support portion 1033 is located between the pillar 1031 and the base 101. The pillar 1031 protrudes from the support portion 1033. An outside diameter of the pillar 1031 gradually increases from the free end 1131 of the pillar 1031 to the other end 1231 of the pillar 1031 close to the base 101, to form a draft on the external surface 1331 of the pillar 1031. The pillar 1031 defines a screw hole 1032 at the free end 1131. The screw hole 1032 is used for receiving a nut (not shown).

In this embodiment, the support portion 1033 includes a platform 1034 which is perpendicular to the pillar 1031 and at least one support leg 1035 which is perpendicular to the platform 1034. The support leg 1035 is perpendicularly protruding from the inner surface 1011 of the base 101 to support the platform 1034.

Moreover, the platform 1034 is a plate, and the platform 1034 is perpendicular to the pillar 1031. The support legs 1035 are also plates. In this embodiment, the at least one the support leg 1035 includes two support legs, and the two support legs 1035 are parallel to each other and perpendicularly connected to the platform 1034. In other embodiments, the two support legs 1035 may intersect with each other and perpendicularly connected to the platform 1034. In another embodiment, the at least one support leg 1035 is a cylinder and perpendicularly connected to the platform 1034.

In addition, the lug boss 103 further includes a plurality of radially extending reinforcing ribs 1036 formed on an outside surface 1331 of the pillar 1031 and the reinforcing ribs 1036 are connected with an upper surface 1331 of the platform 1034. The reinforcing ribs 1036 are formed together with the pillar 1031 and the support potions 1033 by injection molding. In this embodiment, the lug boss 103 includes four reinforcing ribs 1036 radially extending reinforcing ribs 1036 formed on the outside surface 1331 of the pillar 1031. The four reinforcing ribs 1036 are connected with the upper surface 1331 of the platform 1034. A height of each reinforcing rib 1036 relative to the outside surface 1331 of the pillar 1031 gradually decreases in a direction away from the base 101.

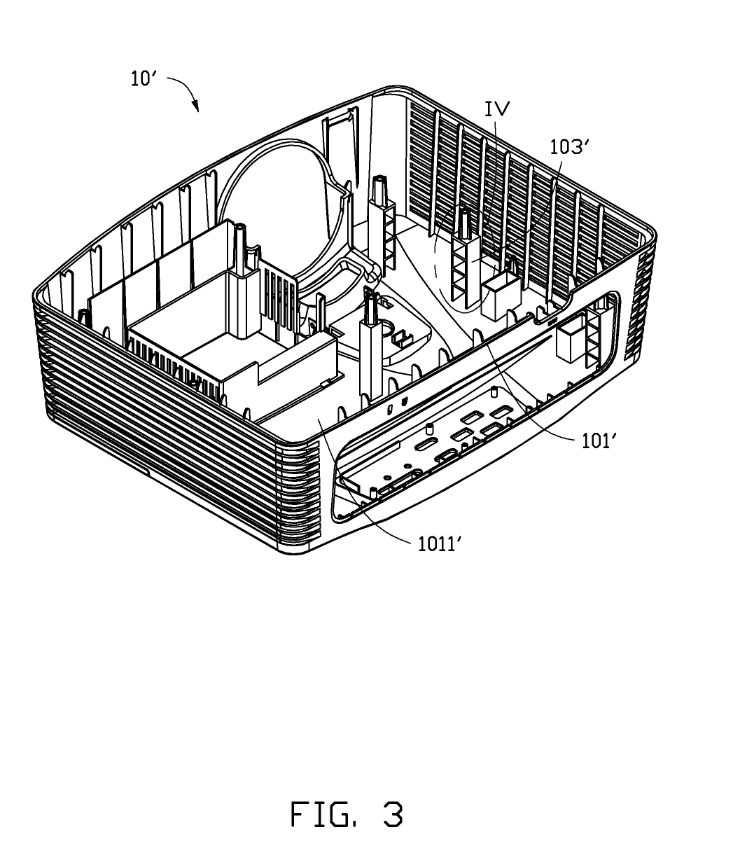

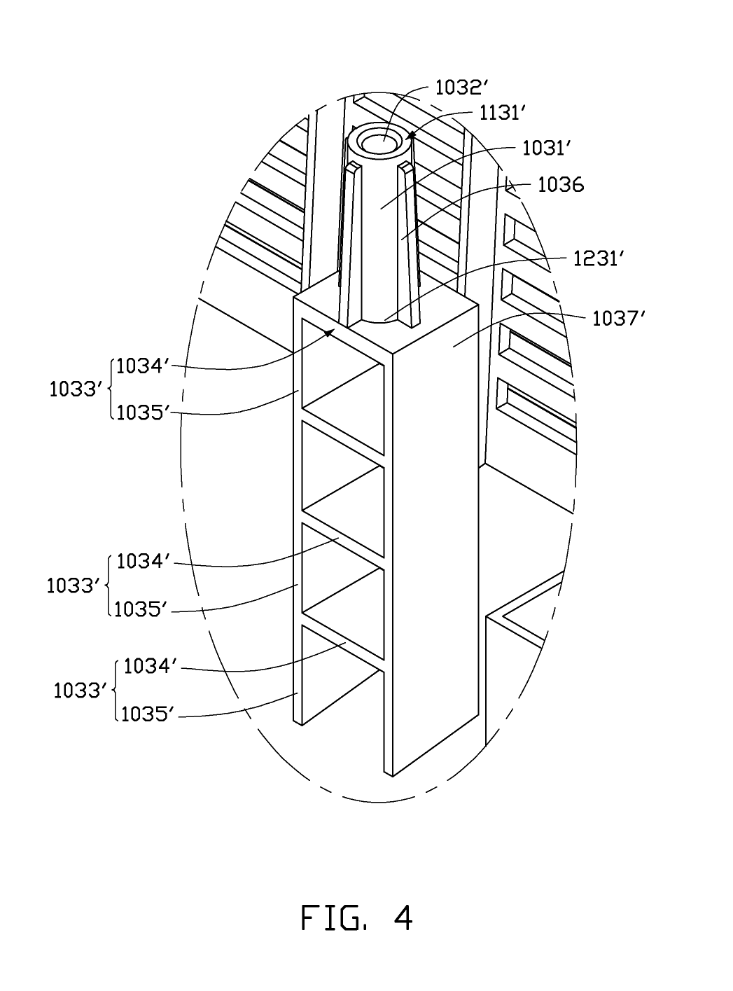

FIGS. 3 and 4 show in another embodiment a plastic shell 10′ includes a base 101′ and at least one lug buss 103′ protruding from the inner surface 1011′ of the base 101′. The lug buss 103′ includes a pillar 1031′ and a support portion 1037′. The support portion 1037′ is positioned on the base 101′ and is located between the base 101′ and the pillar 1031′. The pillar 1031′ extends from the support portion 1037′. An outside diameter of the pillar 1031′ gradually increases from one free end 1131′ of the pillar 1031′ to the other end 1231′ of the pillar 1031′ close to the base 101′. The pillar 1031′ defines a screw hole 1032′ at the free end 1131′. The screw hole 1032′ is used for receiving a nut (not shown).

The support portions 1037′ includes more than one support element 1033′. The support elements 1033′ are stacked with each other to form the support portions 1037′. Every support elements 1033′ includes a platform 1034′ which is perpendicular to the pillar 1031′ and at least one support leg 1035′ which is perpendicular to the platform 1034′. The support legs 1035′ of the upper support portions 1033′ is perpendicularly protruding from the platform 1034′ of the lower support portions 1033′.

In one embodiment, a height of the lug boss is constant, and the lug boss 103 includes the support potion 1033 and the pillar 1031 extending from the support potion 1033, the higher the support potion 1033, the lower the pillar 1031. Even though the outer surface 1331 of the pillar 1031 has a draft. If the pillar 1031 is lower, a thickness of the pillar 1031 is substantially even. In addition, a thickness of the support potion 1033 is also even. A thickness of lug bosses 103 is thus substantially even, and a thickness of the base 101 of plastic shell 10 is also even. Therefore, a thickness of the plastic shell 10 is even and a plastic shell 10, which has an evenly thick will be relatively shrink-proof during the injection molding process.

What is claimed is:

1. An anti-shrink plastic shell comprising
a base;
at least one lug boss protruding from an inner surface of the plastic shell;
wherein the lug boss includes a pillar and a support portion positioned between the base and the pillar; the support portion includes a platform which is perpendicular to the pillar and at least one support leg which is perpendicular to the platform, and the at least one support leg perpendicularly protrudes from the inner surface of the base to support the platform.

2. The anti-shrink plastic shell of claim 1, wherein the at least one support leg is a plate and the platform is a plate.

3. The anti-shrink plastic shell of claim 2, wherein the at least one the support leg includes two support legs, and the two support legs are parallel to each other.

4. The anti-shrink plastic shell of claim 2, wherein the at least one support leg includes two support legs, and the two support legs intersect with each other.

5. The anti-shrink plastic shell of claim 2, wherein the at least one support leg is cylinder and the platform is a plate.

6. The anti-shrink plastic shell of claim 1, wherein the lug boss comprises a plurality of radially extending reinforcing ribs formed on an outside surface of the pillar, and the reinforcing ribs are connected with an upper surface of the platform.

7. The anti-shrink plastic shell of claim 6, wherein a height of each reinforcing rib relative to the outside surface of the pillar gradually decreases in a direction away from the base.
